(19) United States
(12) Patent Application Publication
(10) Pub. No.: US 2013/0038970 A1
(43) Pub. Date: Feb. 14, 2013

(54) SURGE PROTECTED DEVICES AND METHODS FOR TREATMENT OF WATER WITH ELECTROMAGNETIC FIELDS

(71) Applicant: Patrick J. Hughes, Vienna, VA (US)

(72) Inventor: Patrick J. Hughes, Vienna, VA (US)

(21) Appl. No.: 13/550,390

(22) Filed: Jul. 16, 2012

Related U.S. Application Data
(60) Provisional application No. 61/522,154, filed on Aug. 10, 2011.

(51) Int. Cl. H02H 9/04; H05K 3/30

(52) U.S. Cl. 361/56; 29/832

(57) ABSTRACT

Devices for treating water are provided with a varistor to protect the circuitry within such devices against excessive voltage surges and/or transient voltages. The varistor is incorporated into the circuitry in such a way that, when triggered by a high voltage spike (e.g., power surge), the varistor shunts the current created by the high voltage spike away from other sensitive components of the circuitry. Methods for treating water using devices that incorporate the varistor are also provided.

### RELATED APPLICATION

This application is related to, and claims the benefit of priority from, U.S. Provisional Application No. 61/522,154 filed Aug. 10, 2011 the contents of which are incorporated by reference herein, as if set forth in full herein.

### BACKGROUND

Devices and methods that use electromagnetic fields and energy to purify or alter the characteristics of water are well known. For example, U.S. Pat. No. 5,326,446, issued to Binger on Jul. 5, 1994, discloses methods and devices for purifying water of mineral impurities and biological contaminants (e.g., bacteria, protozoa, algae and fungi). The devices and methods of the Binger patent employ a static electromagnetic field capable of treating ionic (mineral) impurities, a low frequency varying electromagnetic field for handling biological contaminants and a high frequency (radio frequency) varying electromagnetic field for handling biological contaminants and breaking up scale formations. The electromagnetic fields of the Binger devices and methods are applied in conjunction with a high output of negative ions into the water. This combination of electromagnetic fields and ionic generation is capable of attacking a broad spectrum of impurities and contaminants commonly found in water.

However, the circuitry employed in the devices such as those disclosed in the Binger patent can be susceptible to damage from excessive transient voltages, such as voltage spikes resulting from power surges. It is therefore desirable to provide devices and methods for purifying water that are capable of treating a broad spectrum of contaminants while at the same time being resistant to damage from excessive transient voltages.

### SUMMARY

Devices and methods for purifying water are provided.

According to an embodiment, an electromagnetic field generator comprising a varistor operable to shunt current created by a high voltage spike to protect circuitry components configured to generate static and varying electromagnetic fields within water is provided.

In another embodiment, a method is provided for protecting circuitry components, the method comprising: connecting a varistor to circuitry components configured to generate static and varying electromagnetic fields within water; and shunting current created by high voltage spikes using the varistor.

According to another embodiment, a method for treating, purifying and decontaminating water includes treating water with a device including an electrode adapted for immersion in the water, and an electromagnetic field generator. The method includes: the generation of a high voltage static electromagnetic field, a low frequency varying electromagnetic field and a high frequency varying electromagnetic field by an electromagnetic field generator; the application of the so generated fields in combination to cleanse the water of a broad spectrum of impurities and contaminants; and, for example, the shunting of current created by high voltage spikes away from sensitive components of the generator's circuitry using, for example a triggered varistor incorporated into the circuitry.

Additional features and advantages of the invention will become clear to those skilled in the art from the following detailed description and appended drawings.

### BRIEF DESCRIPTION OF THE DRAWINGS

FIG. 1A is an electronic schematic showing circuit elements of a device for purifying water, according to an embodiment.

FIG. 1B is a graphic representation of an electromagnetic signal generated by the device of FIG. 1.

FIG. 2 is a cross sectional view of a water purifying unit utilized within a conduit containing a flow of water to be treated, according to an embodiment.

FIG. 3 is a cross sectional view of a water purifying unit utilized within a conduit containing a flow of water to be treated, according to another embodiment.

FIG. 4 is a perspective view of an arrangement of electrodes suitable for cooling tower water purification, according to an embodiment.

FIG. 5 is a cross sectional view of an arrangement of electrodes, according to another embodiment.

### DETAILED DESCRIPTION

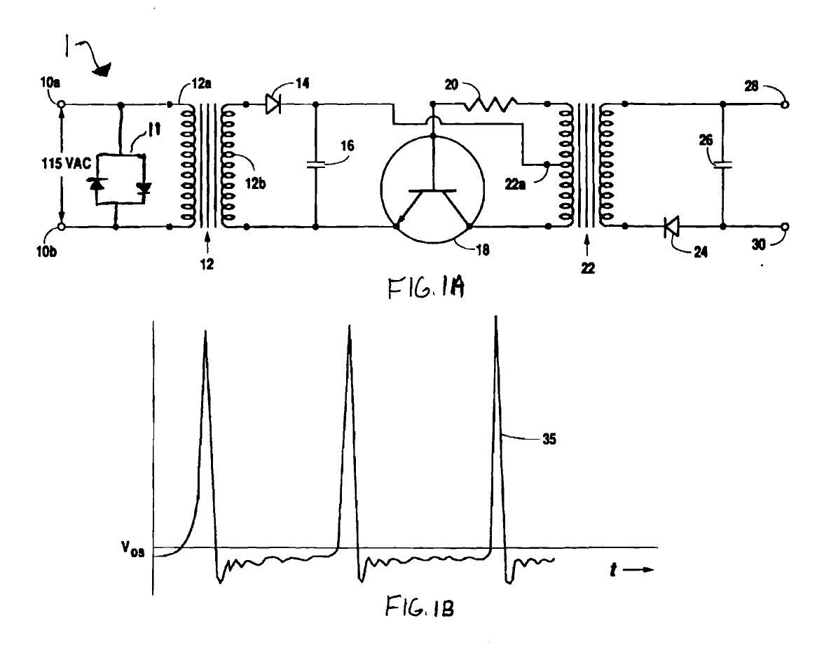

FIG. 1A shows a power circuit (1), which is the circuitry of a device for purifying water, according to an embodiment of the invention. A standard 115-volt AC power supply is connected across terminals (10a) and (10b) at the input to the circuit (1). The primary components of the circuit (1) include a step-down transformer (12), an oscillating transistor (18), a step-up transformer (22), and a varistor (11) (also known as a Voltage Dependent Resistor, or VDR). While a varistor (11) is shown being used in circuit (1) it should be understood that other equivalent surge protective/suppressing devices/components may be used. The power supply powers the primary winding (12a) of the step-down transformer (12). The step-down transformer (12) has a secondary winding (12b) that can provide, for example, three volts to twelve volts at 0.3 amps. This voltage is then provided to a center tap (22a) of the step-up transformer (22) by way of a diode (14). In a preferred embodiment, the diode (14) can be a 500-volt diode with a 1 amp rating. A filtering capacitor (16), such as a 330 microfarad capacitor rated at 25 volts, can be provided in parallel with the secondary winding (12b) of the transformer (12), with the diode (14) connected between one lead of the secondary winding (12b) and one lead of the capacitor (16).

The combination of the transistor (18), which can be an NPN power transistor rated at 30 watts in a preferred embodiment, and the step-up transformer (22) creates an oscillator that outputs a voltage varying in a whole range of radio frequencies. The step-up transformer (22) can have a primary 6 volt center tap coil and a secondary coil with a 25 to 1 ratio rated at 1,500 volts at 10 milliamps, for example. A resistor (20) can be used to provide the base voltage to the transistor (18). The resistor (20) can have a resistance of 390 ohms to 9,100 ohms, for example.

The varistor (11) is placed on the incoming wiring of the circuit (1) between the terminals (10a) and (10b) and the step-down transformer (12) in order to protect the circuit against excessive voltage surges and/or transient voltages. According to an embodiment, the varistor (11) can be a varistor rated at 130 volts and 10 amps, such as a model S14K varistor manufactured by Chenut Ferral. However, other types of varistors having different nominal voltage and current ratings can be used. In operation, the varistor (11) is triggered by high voltage spikes (e.g., voltage spikes caused by power surges), such that the varistor (11) will shunt the current created by such high voltage spikes away from the other, sensitive components of the circuit (1).

The exemplary circuit (1) described above provides radio frequency oscillations at the output of step-up transformer (22). The signal output by the circuit (1) is conditioned by a diode (24), which can be, for example, a 10,000 volt diode rated at 20 milliamps, and by a capacitor (26), which can be, for example, an 800 picofarad capacitor rated at 10,000 volts. This provides a radio frequency signal across the terminals (28) and (30) that are connected to the electrodes (described in more detail below) of the water purifying device.

The operation of the above described circuit (1) creates a wave form similar to that shown in FIG. 1B. The reference base line shown in FIG. 1B (V_{OS}) may be any DC offset desirable for the particular application involved. The importance of the output, however, lies in the waveform and the spiked pulses that the combination of radio frequencies periodically put out. This voltage spike of up to 2,000 volts or more results from the positive reinforcement of these radio frequencies on an intermittent basis. The frequency of the pulse itself provides the low frequency signal necessary for certain types of water purification. At the same time, the underlying radio frequencies in the signal provide the necessary electromagnetic fluctuations to eliminate other types of impurities in the water being treated. The pulse width of the waveform (35) described in FIG. 1B is approximately 10 microseconds. This pulse width, however, can be controlled by appropriate adjustment of the biasing of the transistor (18) shown in FIG. 1A. All of the characteristics of the output waveform (35) shown in FIG. 1B can be modified by appropriate biasing and resistance and capacitance changes to the circuitry in FIG. 1A. The resistor (20), for example, can be replaced by a variable resistor (not shown) that would allow user modification of the output frequencies. The only critical characteristics of the waveform are the inclusion of its underlying radio frequency, its low frequency pulse structure, the high voltage level of the pulse and the short pulse widths of the spikes. The combination of all of these wave elements enables the circuitry to drive electrodes in a number of different applications.

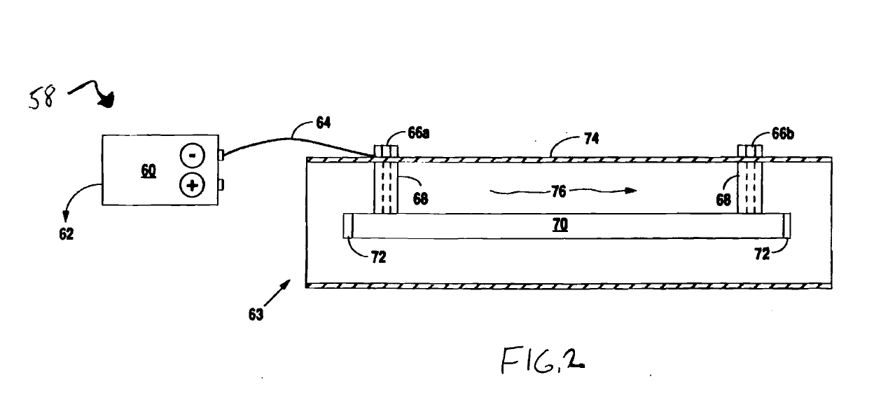

FIG. 2 shows a cross sectional view of an electrostatic water purifying unit (58) according to an embodiment of the invention. A power unit (60) comprising the circuit (1) of FIG. 1 (or similar circuitry) is connected to a standard AC power source (62) as described above with respect to FIG. 1A. A negative output (64) of the power unit (60) is connected to a PVC electrode unit (63) at a first stainless steel bolt (66a). The stainless steel bolt (66a) passes through the wall of a PVC pipe (74) and can be attached to a proximal end of a stainless steel core electrode (70). The stainless steel core electrode (70) is spaced from the interior wall of PVC pipe (74) by way of an insulating spacer (68). The stainless steel core electrode (70) can be a stainless steel tube of a length appropriate for sufficient contact with water within the flow of the pipe. Typically, the length of the core electrode (70) can be anywhere from 8″ to 32″, depending upon the application. The stainless steel electrode (70) can be closed at its proximal and distal ends by plugs or caps (72). The distal end of the stainless steel electrode (70) can also be attached and held in place within the PVC pipe (74) by way of a second stainless steel bolt (66b). A spacer (68) can also be provided in this attachment in order to keep the stainless steel electrode (70) centered within the PVC pipe (74). A flow of water (76) can then be passed around and about the stainless steel electrode (70), with the flow of water (76) being purified as it proceeds along the electrode (70). Although not shown in FIG. 2, it is assumed that that the water within the flow of the PVC electrode unit (63) is at a ground potential from the grounded metal piping that the water is typically flowing through. It should be understood that the PVC electrode unit (63) could be connected to any of a number of different standard PVC couplings and plumbing fixtures. The diameter of the PVC pipe (74) can be varied according to the type of fixture involved. In a preferred embodiment, the PVC pipe (74) can be a standard 4″ schedule 40 PVC pipe and the stainless steel core electrode (70) can be a standard ¾″ or 1″ stainless steel pipe.

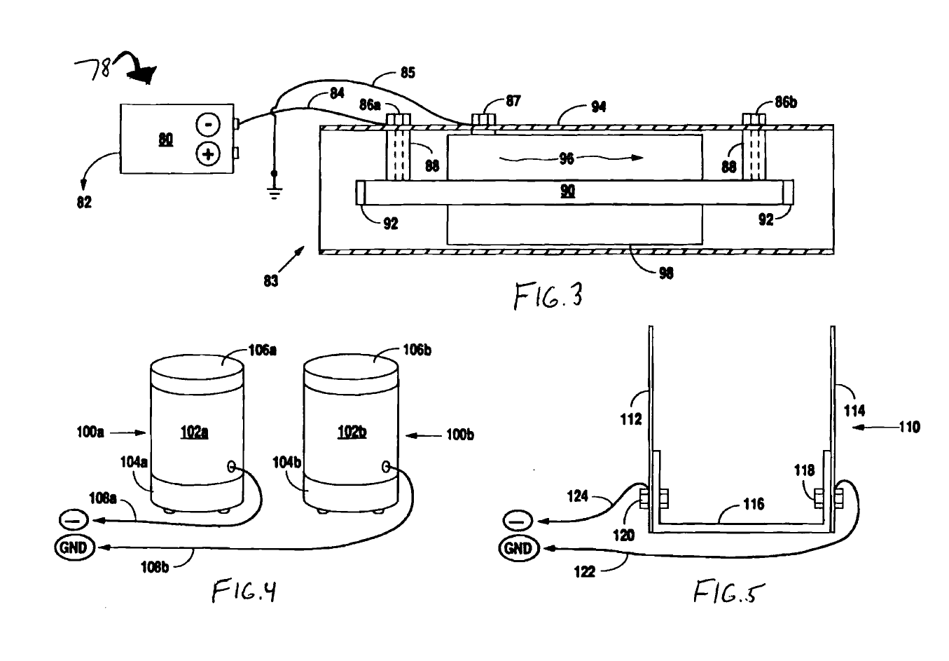

FIG. 3 shows an electrostatic water purifying unit (78) according to another embodiment of the invention. In the unit (78), a PVC electrode unit (83) is connected to a power unit (80) (similar to power unit (60)), which is connected to a standard AC power source (82). In this case, the negative terminal (84) of the power unit (80) is connected to a stainless steel centered electrode (90) and a grounded terminal (85) is connected to a surrounding ground electrode (98) to provide the ground potential in completely ungrounded systems, such as PVC irrigation systems. The negative terminal (84) can be connected to the proximal end of the stainless steel centered electrode (90) by way of a stainless steel bolt (86a) and a spacer (88). The stainless steel electrode (90) can be closed at its proximal and distal ends by plugs or caps (92).

The surrounding ground electrode (98) is placed within a PVC pipe (94). The ground output (85) from the power unit (80) can be connected through the wall of the PVC pipe (94) by way of a stainless steel bolt (87). The stainless steel bolt (87) can be attached to a stainless steel inner liner of the ground electrode (98) that surrounds, but is not in contact with the stainless steel electrode (90). Water flow (96) passes within and between the stainless steel inner liner of the ground electrode (98) and the stainless steel electrode (90).

As with the PVC electrode unit (63) described in FIG. 2, the PVC electrode unit (83) can easily be connected to any of a number of PVC plumbing fixtures through standard PVC couplings, adapters, etc. The dimensions of the PVC electrode unit (83) can be similar to those previously described (e.g., 1″ to 2″, or 4″ to 24″ for very large PVC fixtures).

The embodiments disclosed in FIGS. 2 and 3 are suitable primarily for installations where a constant flow of water past the electrodes is anticipated. However, the water purifying units (58, 78) of these embodiments can be easily converted to canister-type units for installation in containers. One such canister-type unit is disclosed in U.S. Pat. No. 4,419,206, wherein two electrodes are immersed in water contained within a canister that circulates by turbulent flow. Any number of different electrode configurations can be used according to a particular intended application for the water purifying units (58, 78).

FIGS. 4 and 5 are directed towards embodiments for larger scale applications, in which electrodes (100a, 100b, 110) are to be installed within large industrial operations such as cooling towers for power plants and the like.

In a typical cooling tower installation, the water being circulated resides primarily in a shallow pool at the base of the cooling tower. Through various means, the water is raised and lowered and is cooled in the process. The electrodes (100a, 100b) shown in FIG. 4 are designed to be placed within the pool of water at the base of the cooling tower and to impart the necessary electromagnetic fields to the water to carry out the purification and decontamination process. The electrodes (100a) and (100b) are of fairly simple construction and are primarily constructed of rolled stainless steel sheets (102a) and (102b). These rolled stainless steel sheets (102a) and (102b) can be large stainless steel cylinders on the order of 8″ to 18″ in diameter, for example. The outer surface area of the electrodes (100a) and (100b) that comes into contact with the water is more important than the cross-sectional configuration of the electrodes. Plastic bases (104a) and (104b) are provided to stainless steel rolled cylinders (102a) and (102b) to elevate the cylinders to an appropriate level within the water pool. Plastic caps (106a) and (106b) can be used to prevent the presence of stagnate water within the center of electrodes (100a) and (100b). In a preferred embodiment, the electrode (100a) is connected to the negative terminal of a power unit (80) described above by way of an insulated electrical conductor (108a). Likewise, a second electrode (100b) is connected to the ground output of the power unit (80) by way of an insulated electrical conductor (108b).

It is noted that it is possible to operate the systems of the present disclosure with only a single negative electrode, as long as the water flows through grounded piping and conduits within the water cooling tower.

FIG. 5 illustrates an embodiment in which a single, dual-plate electrode unit (110) is used in place of the double electrodes (100a, 100b) described in FIG. 4. The dual-plate electrode unit (110) includes first and second stainless steel electrode plates (112) and (114) mounted on plastic base (116) which raises the electrode plates (112) and (114) appropriately above the pool floor of a cooling tower unit. The first stainless steel electrode plate (112) can be connected to the plastic base (116) by way of a stainless steel bolt (120). The negative output of the power unit (80) can be connected to the first stainless steel plate (112) at the stainless steel bolt (120) by way of an electrical conductor (124). Likewise, the second stainless steel plate (114) can be connected to an opposite side of the plastic base (116) by way of a stainless steel bolt (118). The ground output of the power unit (80) can be connected to the second stainless steel plate (114) at the stainless steel bolt (118) by way of an electrical conductor (122). The electrode plates (112) and (114) can be generally rectangular in structure and the base (116) can be suitably shaped to hold the electrode plates (112) and (114) in an orientation perpendicular to the pool floor of the cooling tower unit.

The size of the pool, the magnitude of the static voltage, and the availability of grounding locations will dictate whether the arrangement of FIG. 4 or the arrangement of FIG. 5 is more suitable.

As described above, the power units disclosed herein can be used in different modes depending upon the particular application. Adjustments to the power unit to emphasize a static electromagnetic field offset or a particular combination of radio frequency and low frequency pulses can be made. In general, it is the radio frequency components of the output signal that prevents the buildup of scaling deposits directly on the electrodes themselves. For example, it has been found in the embodiment of FIG. 4 that there is a reduction in the formation of scale within the cooling tower unit, the electrodes do not require cleaning, and the mineral content of the water eventually precipitates out as a fine silt in the base of the cooling tower pool. Because of the radio frequency signals, the presently disclosed systems also break up scale that has accumulated within a water conduit or container, and will eventually remove such scale to again be silted out in a fine powder form.

The radio frequencies also contribute to the effectiveness of the system in sterilizing and decontaminating water containing bacteria, amoeba, protozoa, algae, fungus, etc. The fast rising spike in the signal (as opposed to merely the implementation of low amplitude radio frequency waves) is critical to this biological contaminant purification. This low frequency spike appears to act as a shock to the bacteria, amoeba, protozoa, etc., within the water and breaks down their protective mechanisms.

When the power unit is used primarily as a high static high voltage generator, as in descaling applications, the preferred voltage output is generally between 2,000 and 5,000 volts. The system can function with a static field as low as 1,000 volts and as high 10,000 volts. However, there appears to be no improvement in operation above 3,000 volts.

When the power unit is used as a combination static high voltage generator and a high negative ion generator, the preferred output voltage is generally between 3,500 and 5,000 volts static field. When the power unit is used strictly as a negative ion generator, the preferred output voltage is 1,500 to 3,000 volts static field with a resultant negative ion output of approximately 100 to 2,000 volts.

When the power unit is used to control bacteria, ameba, protozoa, algae, fungus, etc., the power unit pulse rate frequency is set to coincide with generally accepted frequencies that control particular types of organisms. For example, the control frequency for E. Coli bacteria is generally known to be 802 cycles per second. The voltage output on such frequencies is preferably between 2,000 and 5,000 volts.

It should be apparent that the foregoing describes only selected embodiments of the invention, and numerous changes and modifications may be made to the embodiments disclosed herein by one of ordinary skill in the art without departing from the general spirit and scope of the invention.

We claim:

1. An electromagnetic field generator comprising:
a varistor operable to shunt current created by a high voltage spike to protect circuitry components configured to generate static and varying electromagnetic fields within water.

2. A method for protecting circuitry components comprising:
connecting a varistor to circuitry components configured to generate static and varying electromagnetic fields within water; and
shunting current created by high voltage spikes using the varistor.
